(19) United States
(12) Patent Application Publication
(10) Pub. No.: US 2002/0089436 A1
(43) Pub. Date: Jul. 11, 2002

(54) Delta data compression and transport

(76) Inventor: Shalom Yariv, Bet Shemesh (IL)

Correspondence Address: DANIEL J SWIRSKY, PO BOX 2345, BEIT SHEMESH, 99544, IL

(21) Appl. No.: 09/757,636

(22) Filed: Jan. 11, 2001

(51) Int. Cl. H03M 7/34

(52) U.S. Cl. 341/51

(57) ABSTRACT

A method of expressing a target symbol sequence T relative to a reference symbol sequence R including identifying a first LCS of symbols in sequences T and R, defining the first LCS as a root node of a tree, the root node being a parent node, for each portion of the sequence T that precedes or succeeds the LCS in the sequence T, where there is a portion of the sequence R corresponding to the portion of the sequence T, identifying a subsequent LCS of symbols in the portions, if the subsequent LCS is identified, defining the subsequent LCS as a child node of the parent node, if the subsequent LCS is not identified, defining a child leaf of the parent node, and, where there is no portion of the sequence R corresponding to the portion of the sequence T, defining a child leaf of the parent node.

### FIELD OF INVENTION

The present invention relates to methods and apparatus for compressing data.

### BACKGROUND OF THE INVENTION

Compression of data has long been used for two distinct purposes, to reduce the amount of storage space required to hold data on a storage medium and to reduce the number of bits that must be sent over a communications link to transmit the data. One well-known method for compression is to represent the data to be compressed in terms of its differences from some reference set of data. Multiple occurrences of a given pattern within the data to be compressed are replaced with a shorter sequence of data acting as a placeholder for the pattern. A special case of this approach is run-length encoding, which entails abbreviating repeated consecutive occurrences of a given bit pattern by a single occurrence of that pattern plus a count of the number of times the pattern is repeated.

Compression encoding techniques that find and encode differences between file versions are commonly known as “Delta Compression Algorithms.” Well known Delta Compression Algorithms include the Tichy Block-Move algorithm and the VDELTA algorithm, which may be though of as a combination of the Block-Move and Lempel-Ziv algorithms.

The effectiveness of a compression technique, typically expressed as a factor by which compression reduces the length of the data, often depends on the nature of the data to be compressed, and a method designed for one kind data is not, in general, as effective when applied to other kinds of data. For example, some compression methods that are quite effective when applied to text files are often far less effective when applied to video images, and vice versa. In one technique well-suited for text compression, a target symbol sequence on a first computer is compared to a reference symbol sequence to identify the longest common substring (LCS) of symbols which are common to both symbol sequences. A string v is a substring of a string u if u=u′vu″ for some prefix U′ and suffix u″. The target symbol sequence may be reconstructed at a second computer by transmitting a representation of the target symbol sequence including indices identifying the LCS and other substrings unique to the target symbol sequence, rather than transmitting the target symbol sequence itself, provided that the second computer also has a copy of the same reference symbol sequence.

The two main challenges facing LCS-referenced techniques have been finding an efficient method of identifying LCSs common to target and reference symbol sequences and finding an efficient method of representing the target symbol sequence in terms of LCSs and unique substrings. Unfortunately, LCS techniques known in the art generally apply a generic, byte-by-byte comparison in a single processing thread and with little or no regard to certain file characteristics that might otherwise reduce the number of comparisons required.

The following U.S. Patents are believed to be representative of the current state of the art of differential data compression methods and apparatus: U.S. Pat. Nos. 5,850,565, 5,977,889, 6,012,063, and 6,104,323.

### SUMMARY OF THE INVENTION

The present invention seeks to provide novel methods and apparatus for compressing data to reduce storage and transmission requirements. An efficient method is provided for representing a target symbol sequence in terms of LCSs in common with a reference symbol sequence and substrings unique to the target symbol sequence.

Most data file formats, such as word-processing files, graphics files, and others, exhibit the following features:

Different versions of the same file have are likely to have LCSs near or at the beginning of the file;

LCSs are often located at both ends of different versions of the same file,

Where different versions of the same file have multiple LCSs, the order of occurrence of the LCSs are often the same in both files.

The present invention takes advantage of these file characteristics and favors LCS discovery at both ends of different versions of the same file by left and right-aligning the files being compared and performing LCS discovery from both ends. Furthermore, the present invention employs process branching techniques that are particularly suited for parallel processing implementations, thereby greatly reducing total processing time.

There is thus provided in accordance with a preferred embodiment of the present invention a method of expressing a target symbol sequence T relative to a reference symbol sequence R, the method including the steps of a) identifying a first longest common substring (LCS) of symbols in the sequences T and R, b) defining the first LCS as a root node of a tree, the root node including the first LCS's starting position in the sequence R, either of the first LCS's length and the first LCS's ending position in the sequence R, and the first LCS's starting position in the sequence T, the root node being a parent node, c) for each portion of the sequence T that precedes or succeeds the LCS in the sequence T d) where there is a portion of the sequence R corresponding to the portion of the sequence T e) identifying a subsequent longest common substring (LCS) of symbols in the portions, f) if the subsequent LCS is identified, defining the subsequent LCS as a child node of the parent node, the child node including the subsequent LCS's starting position in the sequence R, either of the subsequent LCS's length and the subsequent LCS's ending position in the sequence R, and the subsequent LCS's starting position in the sequence T, g) if the subsequent LCS is not identified, defining a child leaf of the parent node, the child leaf including the starting position of the portion of the sequence T in the sequence T and the portion of the sequence T itself, and h) where there is no portion of the sequence R corresponding to the portion of the sequence T, defining a child leaf of the parent node, the child leaf including the starting position of the portion of the sequence T in the sequence T and the portion of the sequence T itself.

In another aspect of the present invention the method further includes recursively performing steps c)-h) for any LCS identified in any of the portions, thereby completely expressing the sequence T in the tree.

In another aspect of the present invention the method further includes performing any of the steps a)-h) if the sequences R and T are alphanumeric text sequences In another aspect of the present invention the method further includes performing any of the steps a)-h) if the sequence T is a transformation of the sequence R.

In another aspect of the present invention the method further includes performing any of the steps a)-h) if the sequence R is a word processing file which has undergone modifications to yield a modified word processing file as the sequence T.

In another aspect of the present invention the method further includes storing any of the LCS nodes in a record including an identification byte of a predefined value indicating that the record is a node and a plurality of bytes for storing any of the LCS starting and ending positions and the LCS length.

In another aspect of the present invention the method further includes storing any of the leaves in a record including an identification byte of a predefined value indicating that the record is a leaf and a plurality of bytes for storing the starting position in the sequence and for storing the portion of the sequence T.

In another aspect of the present invention the method further includes storing any of the LCS nodes in a record including an identification byte of a predefined value indicating that the record is a node and a plurality of bytes for storing any of the LCS starting and ending positions and the LCS length, storing any of the leaves in a record including an identification byte of a predefined value indicating that the record is a leaf and a plurality of bytes for storing the starting position in the sequence and for storing the portion of the sequence T, and storing any of the node and leaf records in a single data file having a header including the length of the sequence T followed by the node and leaf records in any order.

There is also provided in accordance with a preferred embodiment of the present invention a method of reconstructing a target symbol sequence T having a known length using a reference symbol sequence R and a tree including any of at least one node, each node including the starting position of an LCS in the sequence R, either of the LCS's length and the LCS's ending position in the sequence R, and the LCS's starting position in the sequence T, and at least one leaf, the leaf including the starting position of a portion of the sequence T in the sequence T and the portion of the sequence T itself, the tree completely expressing the sequence T, the method including the steps of creating an array having a length equal to the length of the sequence T, for each of the nodes retrieving an LCS within reference symbol sequence R at the starting position of the LCS in the sequence R indicated by the node and either of the LCS's length and the LCS's ending position in the sequence R indicated by the node, and inserting the LCS into the array at the LCS's starting position in the sequence T indicated by the node, and for each of the leaves inserting the portion of the sequence T stored within the leaf into the array at the position indicated by the leaf There is also provided in accordance with a preferred embodiment of the present invention a method of expressing a target symbol sequence T relative to a reference symbol sequence R, the method including the steps of a) left-aligning the sequences T and R, b) identifying a first longest common substring (LCS) of symbols in the sequences T and R starting at byte 0 of each sequence, c) defining the first LCS as a root node of a tree, the root node including the first LCS's starting position in the sequence R, either of the first LCS's length and the first LCS's ending position in the sequence R, and the first LCS's starting position in the sequence T, the root node being a parent node, d) for each portion of the sequence T that precedes the LCS in the sequence T e) where there is a portion of the sequence R corresponding to the preceding portion of the sequence T f) left-aligning the preceding and corresponding portions, g) identifying a subsequent longest common substring (LCS) of symbols in the portions starting at byte 0 of each portion, h) if the subsequent LCS is identified, defining the subsequent LCS as a child node of the parent node, the child node including the subsequent LCS's starting position in the sequence R, either of the subsequent LCS's length and the subsequent LCS's ending position in the sequence R, and the subsequent LCS's starting position in the sequence T, i) if the subsequent LCS is not identified, defining a child leaf of the parent node, the child leaf including the starting position of the portion of the sequence T in the sequence T and the portion of the sequence T itself, and j) where there is no portion of the sequence R corresponding to the portion of the sequence T, defining a child leaf of the parent node, the child leaf including the starting position of the portion of the sequence T in the sequence T and the portion of the sequence T itself, and k) for each portion of the sequence T that succeeds the LCS in the sequence T l) where there is a portion of the sequence R corresponding to the succeeding portion of the sequence T m) right-aligning the succeeding and corresponding portions, n) identifying a subsequent longest common substring (LCS) of symbols in the portions starting at the last byte of each portion, o) if the subsequent LCS is identified, defining the subsequent LCS as a child node of the parent node, the child node including the subsequent LCS's starting position in the sequence R, either of the subsequent LCS's length and the subsequent LCS's ending position in the sequence R, and the subsequent LCS's starting position in the sequence T, p) if the subsequent LCS is not identified, defining a child leaf of the parent node, the child leaf including the starting position of the portion of the sequence T in the sequence T and the portion of the sequence T itself, and q) where there is no portion of the sequence R corresponding to the portion of the sequence T, defining a child leaf of the parent node, the child leaf including the starting position of the portion of the sequence T in the sequence T and the portion of the sequence T itself.

It is appreciated throughout the specification and claims that the term “symbol sequence” refers to any sequence of bits, bytes, words, or any other sequence of information coding units.

The disclosures of all patents, patent applications, and other publications mentioned in this specification and of the patents, patent applications, and other publications cited therein are hereby incorporated by reference.

### BRIEF DESCRIPTION OF THE DRAWINGS

The present invention will be understood and appreciated more fully from the following detailed description taken in conjunction with the appended drawings in which:

FIG. 1 is a simplified flowchart illustration of a method of expressing a target symbol sequence relative to a reference symbol sequence, operative in accordance with a preferred embodiment of the present invention;

FIGS. 2 and 3 are simplified pictorial illustrations useful in understanding the method of FIG. 1;

FIG. 4 is a simplified pictorial illustration of a data structure that may be used to store LCS nodes and other substring leaves of FIGS. 2 and 3, constructed and operative in accordance with a preferred embodiment of the present invention;

FIG. 5 is a simplified flowchart illustration of a method of reconstructing a target symbol sequence using a reference symbol sequence, operative in accordance with a preferred embodiment of the present invention;

FIG. 6 is a simplified flowchart illustration of a method of expressing a target symbol sequence relative to a reference symbol sequence, operative in accordance with another preferred embodiment of the present invention; and

FIG. 7 is a simplified pictorial illustration useful in understanding the method of FIG. 6.

### DETAILED DESCRIPTION OF PREFERRED EMBODIMENTS

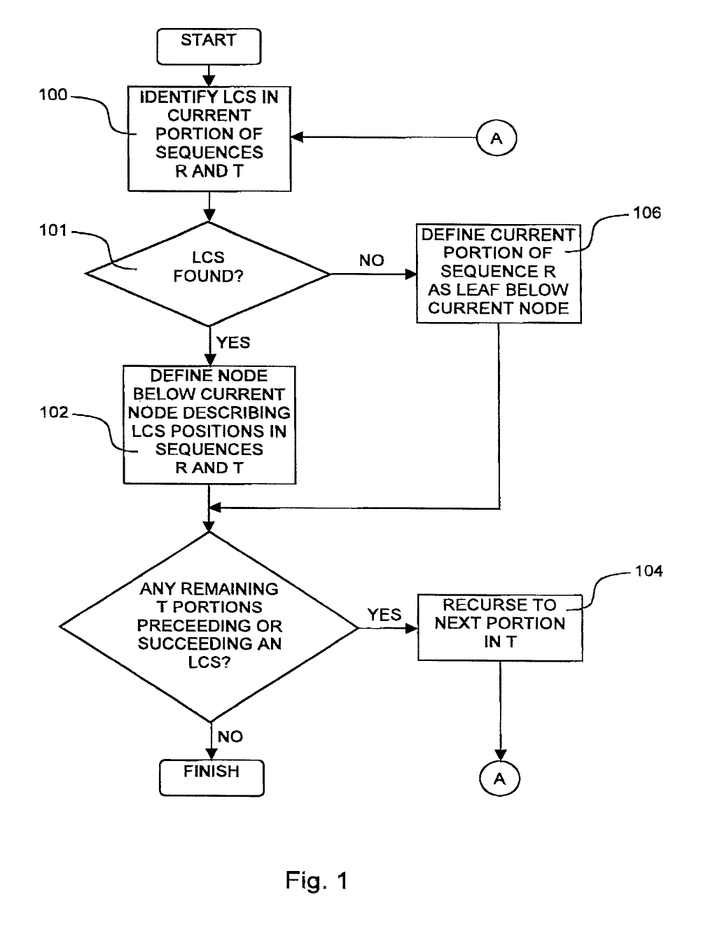

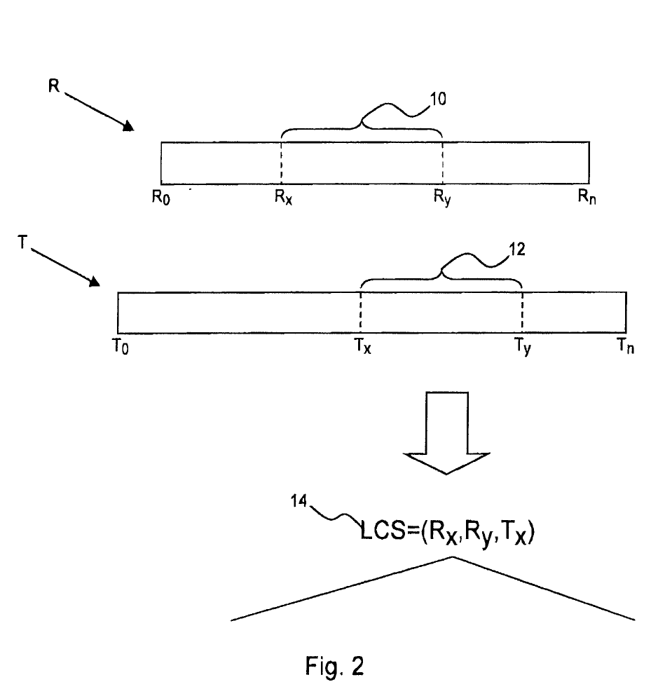

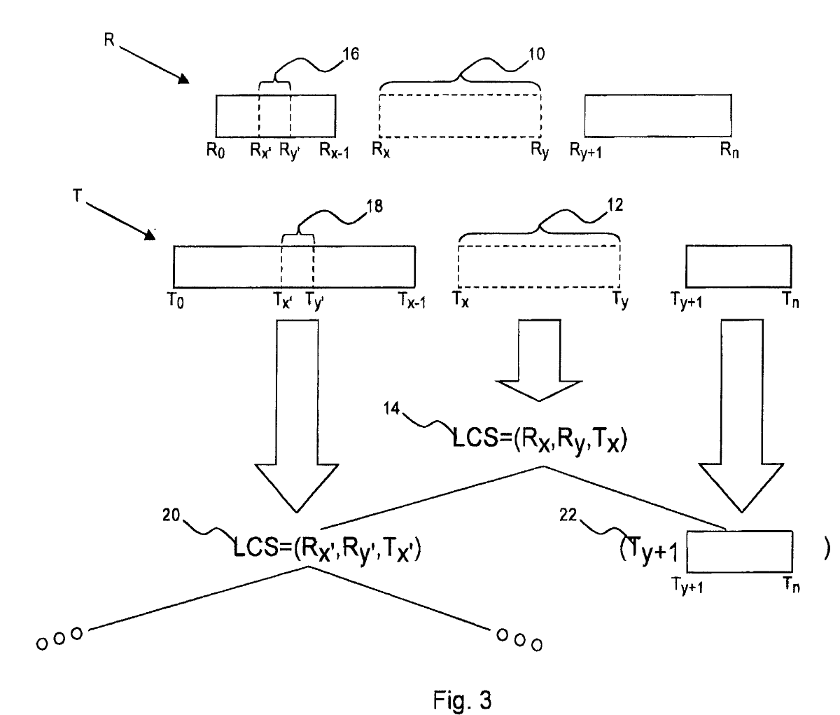

Reference is now made to FIG. 1, which is a simplified flowchart illustration of a method of expressing a target symbol sequence relative to a reference symbol sequence, operative in accordance with a preferred embodiment of the present invention, and additionally to FIGS. 2 and 3, which are simplified pictorial illustrations useful in understanding the method of FIG. 1. In the method of FIG. 1, a target symbol sequence T is compared to a reference symbol sequence R to identify the longest common substring (LCS) of symbols common to both R and T (step 100). Typically, sequences R and T are alphanumeric text sequences, with sequence T representing a transformation of sequence R, such as where sequence R is a word processing file which has undergone modifications to yield a modified word processing file as sequence T. Any LCS discovery technique may be used. For example, as shown in FIG. 2, an LCS 10 in sequence R starting at position Rₓ and ending at position R_{y} is present in sequence T as LCS 12 starting at position Tₓ. The first LCS found (step 101) when comparing sequences R and T is then defined as a root node 14 of a tree, with the LCS being expressed in terms of its starting position in sequence R, either its length or its ending position in sequence R, and its starting position in sequence T (step 102). Thus, in FIG. 2, LCS 10/12 is expressed at root node 14 as (Rₓ,R_{y},Tₓ)

Prefix or suffix portions of sequence T that precede or succeed an LCS in sequence T are then compared with corresponding prefix or suffix portions of sequence R to form left and right branches below an LCS node as follows (step 104). Where an LCS in corresponding prefix or suffix portions of sequences R and T is not found (step 101), the prefix or suffix portion of sequence T is defined as a child leaf under its parent LCS node and is expressed in terms of its starting position in sequence T and the sequence portion itself (step 106). Thus, in FIG. 3, the portion of sequence T that succeeds LCS 12 beginning at position T_{y+1}, having no LCS in common with the corresponding portion of sequence T that succeeds LCS 10, is defined as a leaf 22 on the right branch below root node 14, with leaf 22 including position T_{y+1} and the portion of sequence T between T_{y+1} and Tₙ. Where an LCS in corresponding prefix or suffix portions of sequences R and T is found (step 101), the LCS is then defined as a child node branching from its parent LCS node, and is expressed in terms of its starting position in sequence R, either its length or its ending position in sequence R, and its starting position in sequence T (step 102). Thus, in FIG. 3, an LCS 16 in the portion of sequence R that precedes LCS 10 starting at position R₀ and ending at position Rₓ₋₁ and that corresponds to an LCS 18 in the portion of sequence T that precedes LCS 12 starting at position T₀ and ending at position Tₓ₋₁ is expressed at a node 20 as (R_{x′},R_{y′},T_{x′}).

In this manner sequences R and T may be recursively processed to identify child leaves and child LCS nodes by comparing each portion of sequence T preceding or succeeding an LCS with a corresponding portion of sequence R until a single tree is constructed of nodes and leaves that may then be used to reconstruct sequence T using only the tree and sequence R. Thus, in FIG. 3, the next portions of sequences R and T to be compared would be the portion of sequence R starting at position R₀ and ending at position R_{x′-1} with the portion of sequence T starting at position T₀ and ending at position T_{x′-1}, as well as the portion of sequence R starting at position R_{y′+1} and ending at position Rₓ₋₁ with the portion of sequence T starting at position T_{y′+1} and ending at position Tₓ₋₁.

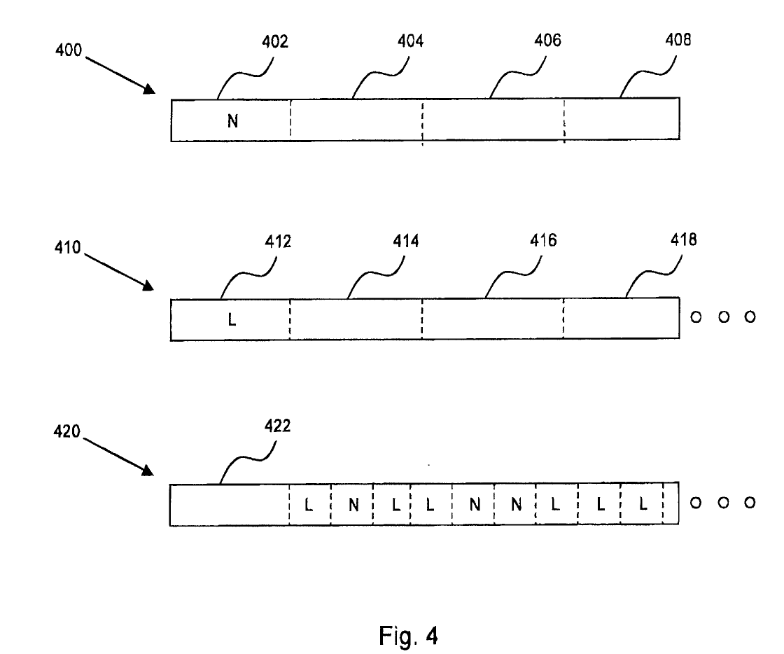

The node and leaf tree constructed using the method of FIG. 1 may be stored using any known method, provided that leaves and nodes are distinguishable from each other. Furthermore, leaves and nodes may be stored and/or transmitted to another computer in any order, as each node and leaf describes a portion of sequence T with reference only to sequence R, and does not require any information from other leaves or nodes. FIG. 4 shows one possible data structure that may be used to store nodes and leaves. In FIG. 4 each node and leaf is stored as a record 400 and 410 respectively, where each node record 400 includes an identification byte 402 of a value such as “N” to indicate that the record is a node, as well as byte positions 404, 406, and 408 for storing the LCS starting and ending positions, and where each leaf record 410 includes an identification byte 412 of a value such as “L” to indicate that the record is a node, as well as byte positions 414, 416, and 418 for storing the starting position in T of the non-LCS sequence and the length of the non-LCS sequence, and for storing the non-LCS sequence itself.

One or more each of the node and leaf records 400 and 410 may be stored as a single data file 420, preferably with a header 422 including the length of the uncompressed sequence T followed by the node and leaf records 400 and 410 is no particular order.

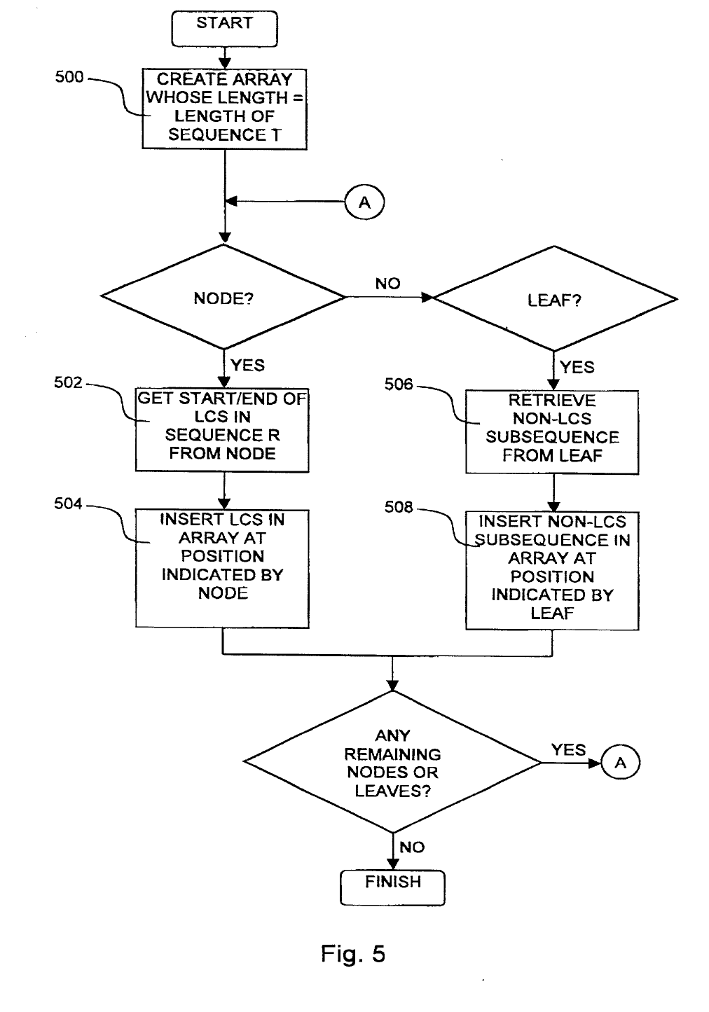

Reference is now made to FIG. 5, which is a simplified flowchart illustration of a method of reconstructing a target symbol sequence using a reference symbol sequence, operative in accordance with a preferred embodiment of the present invention. In the method of FIG. 5, one or more nodes and leaves representing a target symbol sequence T are used to reconstruct the target symbol sequence T using a reference symbol sequence R as follows. An empty array A is created whose length is equal to the length of the original target symbol sequence T, such as is indicated in header 422 of data file 420 (FIG. 4) (step 500). For each node, the LCS within reference symbol sequence R whose starting and ending position in reference symbol sequence R is indicated by the node (step 502) is retrieved from reference symbol sequence R and inserted into array A at the position indicated by the node (step 504). For each leaf, the non-LCS symbol subsequence stored within the leaf is retrieved from the leaf (step 506) and inserted into array A at the position indicated by the leaf (step 508). Steps 502-508 are preferably repeated until all nodes and leaves have been processed (step 510), with array A containing the reconstruction of the original target symbol sequence T.

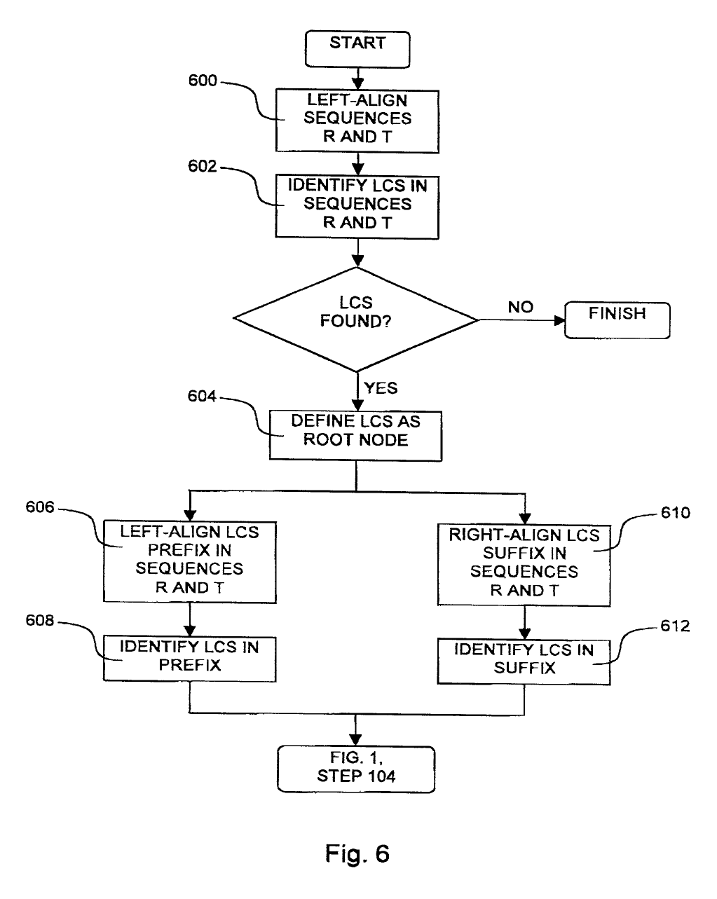

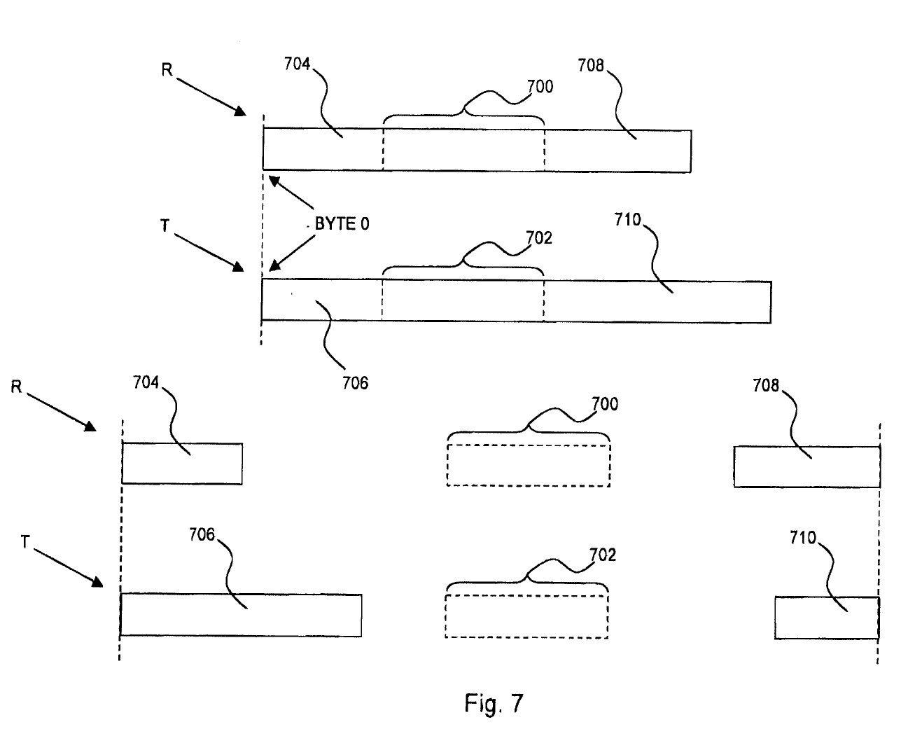

Reference is now made to FIG. 6, which is a simplified flowchart illustration of a method of expressing a target symbol sequence relative to a reference symbol sequence, operative in accordance with another preferred embodiment of the present invention, and additionally to FIG. 7, which is a simplified pictorial illustration useful in understanding the method of FIG. 6. The method of FIG. 6 is preferably employed on target symbol sequence T and reference symbol sequence R of FIGS. 1-3 prior to employing the method of FIG. 1 as follows. In the method of FIG. 6, sequences R and T are both “left-aligned” (step 600), meaning that a byte-by-byte comparison of sequences T and R is undertaken using any suitable LCS technique starting at byte 0 of each sequence to identify the longest common substring (LCS) of symbols common to both R and T (step 602). If an LCS is found, such as LCS 700 and 702 of FIG. 7, it is set as root node 14 as shown in FIG. 2 (step 604). A prefix portion 704 of sequence T relative to the LCS is itself left-aligned with a corresponding prefix portion 706 of sequence R (step 606) and is searched for an LCS (step 608). Processing then continues for prefix portions 704 and 706 and their branching descendents from step 101 of FIG. 1, with LCS-nodes and non-LCS leaves descending from the root LCS node. Similarly, a suffix portion 708 of sequence T relative to the LCS is right-aligned with a corresponding suffix portion 710 of sequence R (step 610) and is searched for an LCS (step 612) starting at the last byte in the two right-aligned suffix portions 708 and 710 and proceeding “leftward” to lower-numbered bytes. Processing then continues for suffix portions 708 and 710 and their branching descendents from step 101 of FIG. 1, with LCS-nodes and non-LCS leaves descending from the root LCS node.

It is appreciated that one or more steps of any of the methods described herein may be implemented in a different order than that shown while not departing from the spirit and scope of the invention.

While the methods and apparatus disclosed herein may or may not have been described with reference to specific hardware or software, the methods and apparatus have been described in a manner sufficient to enable persons having ordinary skill in the art to readily adapt commercially available hardware and software as may be needed to reduce any of the embodiments of the present invention to practice without undue experimentation and using conventional techniques.

While the present invention has been described with reference to one or more specific embodiments, the description is intended to be illustrative of the invention as a whole and is not to be construed as limiting the invention to the embodiments shown. It is appreciated that various modifications may occur to those skilled in the art that, while not specifically shown herein, are nevertheless within the true spirit and scope of the invention.

What is claimed is:

1. A method of expressing a target symbol sequence T relative to a reference symbol sequence R, the method comprising the steps of:
a) identifying a first longest common substring (LCS) of symbols in said sequences T and R;
b) defining said first LCS as a root node of a tree, said root node comprising said first LCS's starting position in said sequence R, either of said first LCS's length and said first LCS's ending position in said sequence R, and said first LCS's starting position in said sequence T, said root node being a parent node;
c) for each portion of said sequence T that precedes or succeeds said LCS in said sequence T:
d) where there is a portion of said sequence R corresponding to said portion of said sequence T:
e) identifying a subsequent longest common substring (LCS) of symbols in said portions;
f) if said subsequent LCS is identified, defining said subsequent LCS as a child node of said parent node, said child node comprising said subsequent LCS's starting position in said sequence R, either of said subsequent LCS's length and said subsequent LCS's ending position in said sequence R, and said subsequent LCS's starting position in said sequence T;
g) if said subsequent LCS is not identified, defining a child leaf of said parent node, said child leaf comprising the starting position of said portion of said sequence T in said sequence T and said portion of said sequence T itself; and
h) where there is no portion of said sequence R corresponding to said portion of said sequence T, defining a child leaf of said parent node, said child leaf comprising the starting position of said portion of said sequence T in said sequence T and said portion of said sequence T itself.

2. A method according to claim 1 and further comprising recursively performing steps c)-h) for any LCS identified in any of said portions, thereby completely expressing said sequence T in said tree.

3. A method according to claim 1 and further comprising performing any of said steps a)-h) if said sequences R and T are alphanumeric text sequences

4. A method according to claim 1 and further comprising performing any of said steps a)-h) if said sequence T is a transformation of said sequence R.

5. A method according to claim 1 and further comprising performing any of said steps a)-h) if said sequence R is a word processing file which has undergone modifications to yield a modified word processing file as said sequence T.

6. A method according to claim 1 and further comprising storing any of said LCS nodes in a record comprising an identification byte of a predefined value indicating that said record is a node and a plurality of bytes for storing any of said LCS starting and ending positions and said LCS length.

7. A method according to claim 1 and further comprising storing any of said leaves in a record comprising an identification byte of a predefined value indicating that said record is a leaf and a plurality of bytes for storing said starting position in said sequence and for storing said portion of said sequence T.

8. A method according to claim 1 and further comprising:
storing any of said LCS nodes in a record comprising an identification byte of a predefined value indicating that said record is a node and a plurality of bytes for storing any of said LCS starting and ending positions and said LCS length;
storing any of said leaves in a record comprising an identification byte of a predefined value indicating that said record is a leaf and a plurality of bytes for storing said starting position in said sequence and for storing said portion of said sequence T; and
storing any of said node and leaf records in a single data file having a header including the length of said sequence T followed by said node and leaf records in any order.

9. A method of reconstructing a target symbol sequence T having a known length using a reference symbol sequence R and a tree comprising any of:
at least one node, each node comprising the starting position of an LCS in said sequence R, either of said LCS's length and said LCS's ending position in said sequence R, and said LCS's starting position in said sequence T, and
at least one leaf, said leaf comprising the starting position of a portion of said sequence T in said sequence T and said portion of said sequence T itself said tree completely expressing said sequence T,
the method comprising the steps of:
creating an array having a length equal to said length of said sequence T;
for each of said nodes:
retrieving an LCS within reference symbol sequence R at the starting position of said LCS in said sequence R indicated by said node and either of said LCS's length and said LCS's ending position in said sequence R indicated by said node; and
inserting said LCS into said array at said LCS's starting position in said sequence T indicated by the node; and
for each of said leaves:
inserting said portion of said sequence T stored within said leaf into said array at the position indicated by said leaf.

10. A method of expressing a target symbol sequence T relative to a reference symbol sequence R, the method comprising the steps of:
a) left-aligning said sequences T and R;
b) identifying a first longest common substring (LCS) of symbols in said sequences T and R starting at byte 0 of each sequence;
c) defining said first LCS as a root node of a tree, said root node comprising said first LCS's starting position in said sequence R, either of said first LCS's length and said first LCS's ending position in said sequence R, and said first LCS's starting position in said sequence T, said root node being a parent node;
d) for each portion of said sequence T that precedes said LCS in said sequence T:
e) where there is a portion of said sequence R corresponding to said preceding portion of said sequence T:
f) left-aligning said preceding and corresponding portions;
g) identifying a subsequent longest common substring (LCS) of symbols in said portions starting at byte 0 of each portion;
h) if said subsequent LCS is identified, defining said subsequent LCS as a child node of said parent node, said child node comprising said subsequent LCS's starting position in said sequence R, either of said subsequent LCS's length and said subsequent LCS's ending position in said sequence R, and said subsequent LCS's starting position in said sequence T;
i) if said subsequent LCS is not identified, defining a child leaf of said parent node, said child leaf comprising the starting position of said portion of said sequence T in said sequence T and said portion of said sequence T itself; and
j) where there is no portion of said sequence R corresponding to said portion of said sequence T, defining a child leaf of said parent node, said child leaf comprising the starting position of said portion of said sequence T in said sequence T and said portion of said sequence T itself; and
k) for each portion of said sequence T that succeeds said LCS in said sequence T:
l) where there is a portion of said sequence R corresponding to said succeeding portion of said sequence T:
m) right-aligning said succeeding and corresponding portions;
n) identifying a subsequent longest common substring (LCS) of symbols in said portions starting at the last byte of each portion;
o) if said subsequent LCS is identified, defining said subsequent LCS as a child node of said parent node, said child node comprising said subsequent LCS's starting position in said sequence R, either of said subsequent LCS's length and said subsequent LCS's ending position in said sequence R, and said subsequent LCS's starting position in said sequence T;
p) if said subsequent LCS is not identified, defining a child leaf of said parent node, said child leaf comprising the starting position of said portion of said sequence T in said sequence T and said portion of said sequence T itself; and
q) where there is no portion of said sequence R corresponding to said portion of said sequence T, defining a child leaf of said parent node, said child leaf comprising the starting position of said portion of said sequence T in said sequence T and said portion of said sequence T itself.
